(19) United States
(12) Patent Application Publication
(10) Pub. No.: US 2026/0096294 A1
(43) Pub. Date: Apr. 2, 2026

(54) ORGANIC LIGHT EMITTING DEVICE AND MANUFACTURING METHOD THEREOF

(71) Applicant: TAIZHOU GUANYU TECHNOLOGY CO., LTD., ZHEJIANG PROVINCE (CN)

(72) Inventors: RENHUI RUAN, ZHEJIANG PROVINCE (CN); KUO-CHENG HSU, TAICHUNG CITY (TW)

(21) Appl. No.: 19/299,361

(22) Filed: Aug. 14, 2025

(30) Foreign Application Priority Data
Sep. 30, 2024 (CN) 202411388333.6

(51) Int. Cl. H10K 59/122; H10K 59/12; H10K 59/80

(52) U.S. Cl. CPC H10K 59/122; H10K 59/1201; H10K 59/80521

(57) ABSTRACT

An organic light emitting device includes a substrate, a first bottom electrode, a first top electrode, a second top electrode, a pixel defined layer and a blocking strip. The first bottom electrode is disposed over the substrate. An organic light emitting layer structure is disposed over the first bottom electrode. The first top electrode and the second top electrode are disposed over the organic light emitting layer structure. The pixel defined layer is disposed over the substrate. The blocking strip is disposed over the pixel defined layer, wherein the first top electrode and the second top electrode are separated by the blocking strip.

### PRIORITY CLAIM AND CROSS-REFERENCE

This application claims the benefit of China patent application No. 202411388333.6, filed on Sep. 30, 2024, the entirety of which are incorporated by reference herein.

### BACKGROUND OF THE DISCLOSURE

### Field of the Disclosure

The present disclosure relates to an organic light emitting device and a manufacturing method thereof, and more particularly to an organic light emitting device including an organic light emitting diode (OLED) structure and a manufacturing method thereof.

### Description of the Prior Art

Currently, a fine metal mask (FMM) is commonly used in a coating step for forming a light emitting layer of an organic light emitting device, or a white light in combination with a color film is used for manufacturing an organic light emitting device. However, the fineness or resolution of pixels resulting from the manufacturing processes above is rather poor.

### SUMMARY OF THE DISCLOSURE

In the present disclosure, an organic light emitting device includes a substrate, a first bottom electrode, a first top electrode, a second top electrode, a pixel defined layer and a blocking strip. The first bottom electrode is disposed over the substrate. An organic light emitting layer structure is disposed over the first bottom electrode. The first top electrode and the second top electrode are disposed over the organic light emitting layer structure. The pixel defined layer is disposed over the substrate. The blocking strip is disposed over the pixel defined layer, wherein the first top electrode and the second top electrode are separated by the blocking strip.

In the present disclosure, a manufacturing method of an organic light emitting device includes: providing a substrate; forming a first bottom electrode over a substrate; forming a pixel defined layer over the substrate, wherein the pixel defined layer partially covers the first bottom electrode; forming a blocking strip over the pixel defined layer, and forming an organic light emitting layer structure over the first bottom electrode and the blocking strip; and forming a top electrode material layer above the blocking strip and the substrate, such that the top electrode material layer is disconnected by the blocking strip to form a first top electrode and a second top electrode that are separated from each other.

In some embodiments, the organic light emitting device further includes an electrode material layer disposed on an upper surface and a sidewall of the blocking strip, and separated from the first top electrode and the second top electrode.

In some embodiments, the organic light emitting device further includes a residue structure disposed on the sidewall of the blocking strip, and the residue structure is separated from the first top electrode and the second top electrode.

In some embodiments, the residue structure includes multiple residues, the residues include electrode material fragments, and the electrode material fragments of at least two different residues are connected.

In some embodiments, at least one of the residues includes an organic material fragment disposed on the sidewall of the blocking strip, and an electrode material fragment disposed on the sidewall of the blocking strip and partially covering the organic material fragment.

In some embodiments, the organic light emitting device further includes a first residue and a second residue. The first residue is disposed on the sidewall of the blocking strip, the second residue is disposed on the sidewall of the blocking strip and is disposed between the first residue and the substrate, wherein the second residue is separated from the first top electrode and the second top electrode.

In some embodiments, the second residue is separated from the first residue.

In some embodiments, the first residue and the second residue include different numbers of material layers.

In some embodiments, the first residue and the second residue have different sizes.

In some embodiments, an included angle between the upper surface and the sidewall of the blocking strip is between 80° and 100°.

In some embodiments, the blocking strip has a sloped sidewall.

In some embodiments, a cross-sectional width of the blocking strip gradually increases in a direction toward the substrate.

In some embodiments, a cross-sectional width of the blocking strip decreases in a direction toward the substrate.

In some embodiments, thickness of the blocking strip is at least 20 times thickness of the first top electrode or the second top electrode.

In some embodiments, the organic light emitting layer structure includes a first organic light emitting layer and a second organic light emitting layer. The first organic light emitting layer is disposed between the first bottom electrode and the first top electrode, and the second organic light emitting layer is disposed between the first bottom electrode and the second top electrode, wherein the first organic light emitting layer is separated from the second organic light emitting layer by the blocking strip.

In some embodiments, the organic light emitting device structure further includes multiple organic material layers disposed at the upper surface of the blocking strip and extending to a top of the sidewall of the blocking strip.

In some embodiments, extension directions of the first top electrode and the second top electrode are substantially parallel to an extension direction of the blocking strip.

In some embodiments, the forming of the blocking strip includes forming a blocking material layer over the pixel defined layer and patterning the blocking material layer to form the blocking strip, wherein an included angle between the upper surface and the sidewall of the blocking strip is between 80° and 100°.

In some embodiments, when the blocking strip disconnects the top electrode material layer, a residue structure is further formed on the sidewall of the blocking strip, wherein the residue structure is separated from the first top electrode and the second top electrode.

In some embodiments, the manufacturing method of an organic light emitting device further includes forming a cover layer above the first top electrode and the second top electrode, wherein the cover layer covers the blocking strip and the residue structure.

### BRIEF DESCRIPTION OF THE DRAWINGS

FIG. 1 is a top view of an intermediate product of an organic light emitting device.

FIG. 2A is a cross-sectional view of an organic light emitting device.

FIG. 2B is a cross-sectional view of an organic light emitting device.

FIG. 2C is a cross-sectional view of an organic light emitting device.

FIG. 2D is a cross-sectional view of an organic light emitting device.

FIG. 3A to FIG. 3D depict a manufacturing method of an organic light emitting device according to some embodiments.

### DETAILED DESCRIPTION OF THE EMBODIMENTS

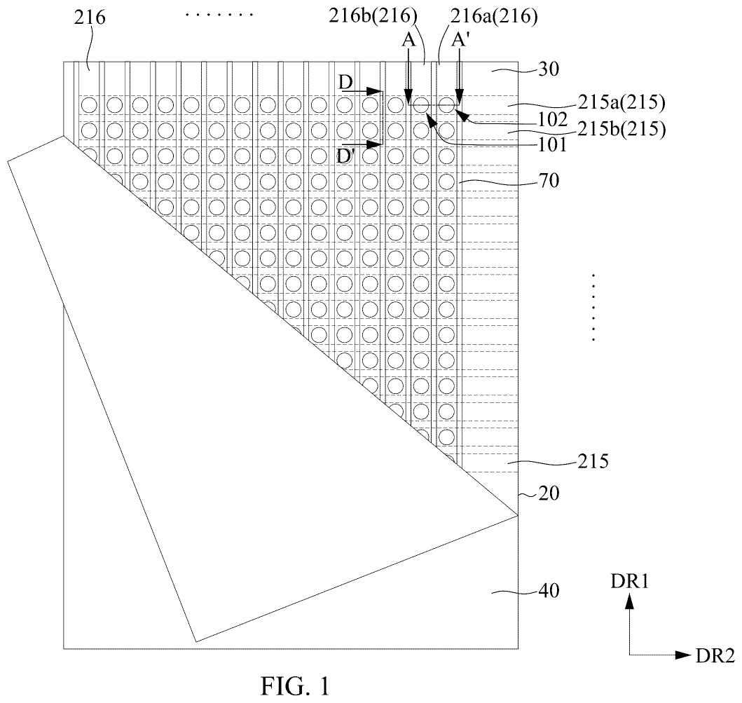

FIG. 1 shows a top view of an intermediate product of an organic light emitting device 10. The organic light emitting device 10 may include a light emitting layer 20 and a cover layer 40 disposed over the light emitting layer 20. For the light emitting layer 20, a spacer structure 30 may be designed to provide an array of recesses for accommodating an array of light emitting pixels. In some embodiments, the spacer structure 30 serves as a pixel defined layer (PDL). In some embodiments, the spacer structure 30 may include a protrusions 310. In some embodiments, the protrusions 310 define a pixel region. In some embodiments, the spacer structure 30 may include a photosensitive material.

As shown in FIG. 1, the organic light emitting device 10 may further include an electrode 215 (or referred to as a bottom electrode) and an electrode 216 (or referred to as a top electrode). In some embodiments, the electrode 215 is an anode and the electrode 216 is a cathode. In some embodiments, the organic light emitting device 10 may include multiple electrodes 215 and multiple electrodes 216, for example, electrodes 215a and 215b, and electrodes 216a and 216b. In some embodiments, an extension direction DR2 of the electrode 215 is substantially perpendicular to an extension direction DR1 of the electrode 216. The organic light emitting device 10 may further include a blocking structure 70 including multiple blocking strips 710. In some embodiments, the extension direction DR1 of the electrode 216 is substantially parallel to the extension direction DR1 of the blocking strips 710. In some embodiments, the extension direction DR2 of the electrode 215 is substantially perpendicular to the extension direction DR1 of the blocking strips 710.

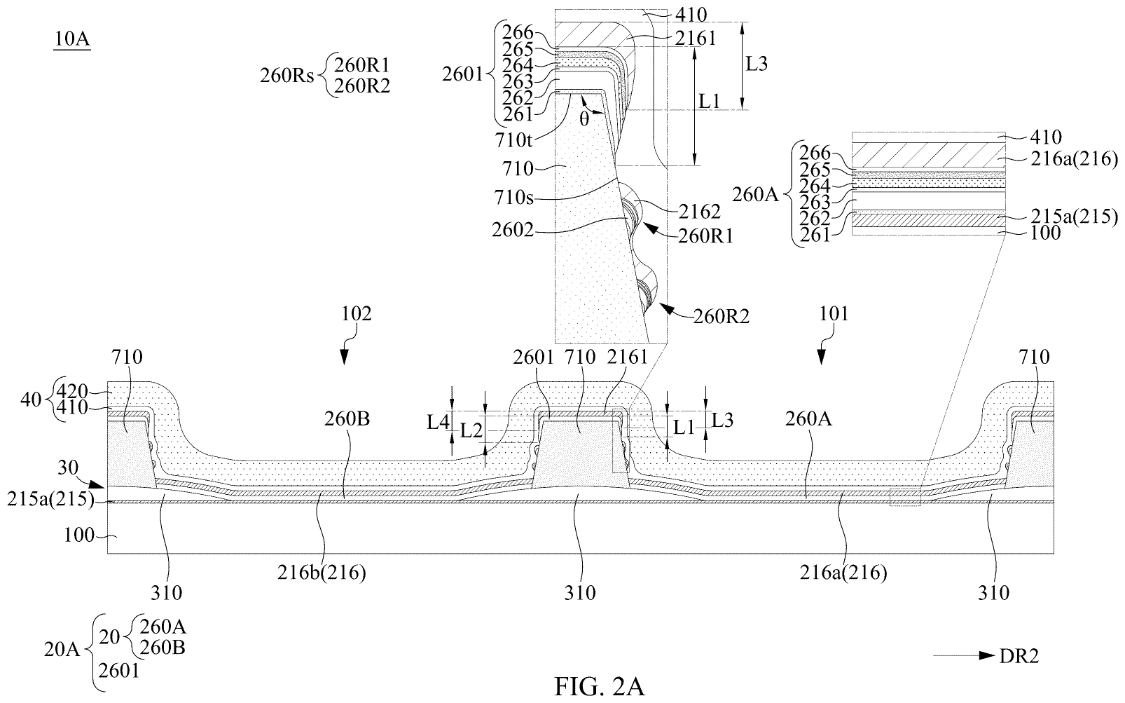

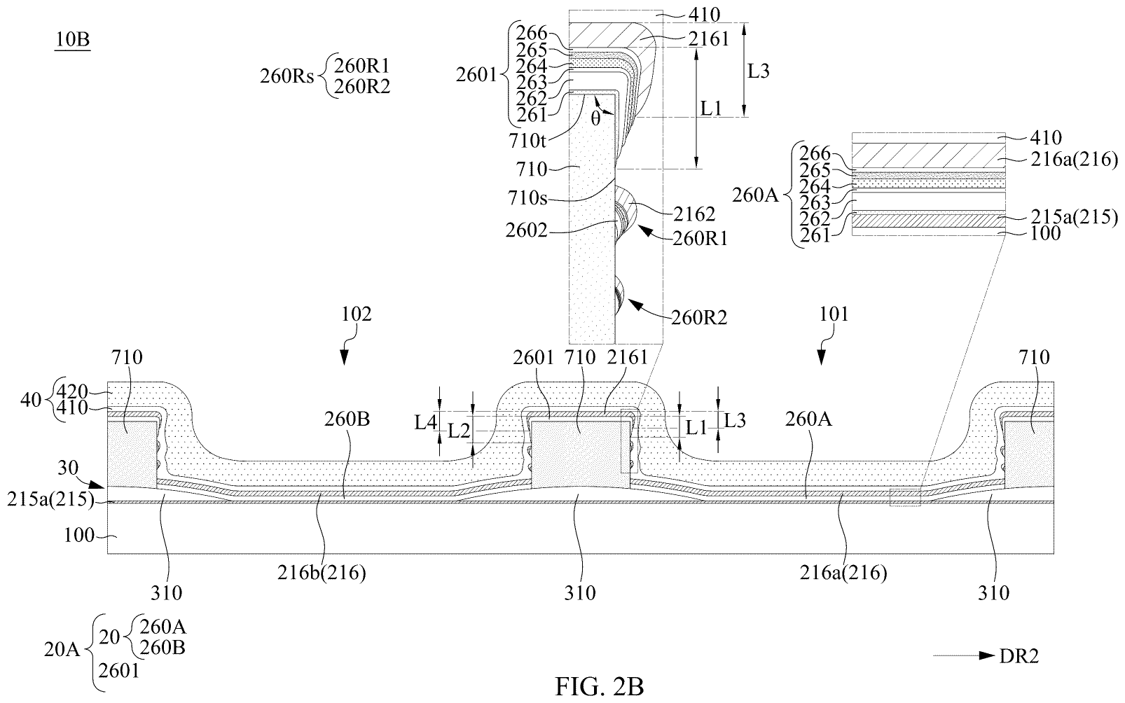

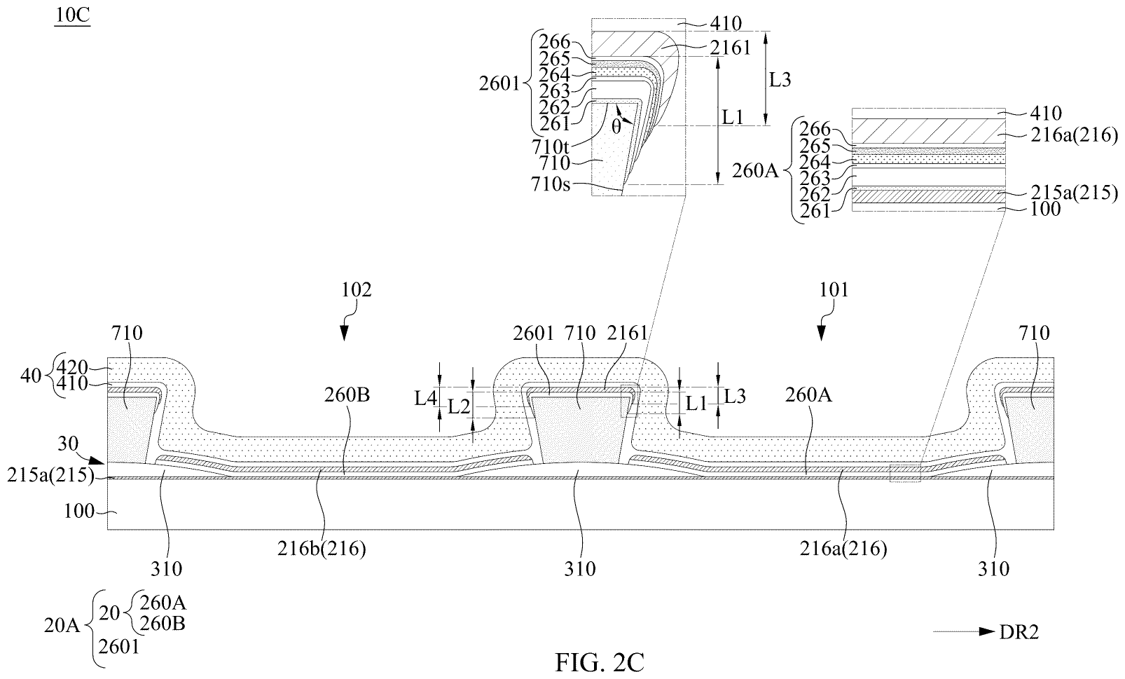

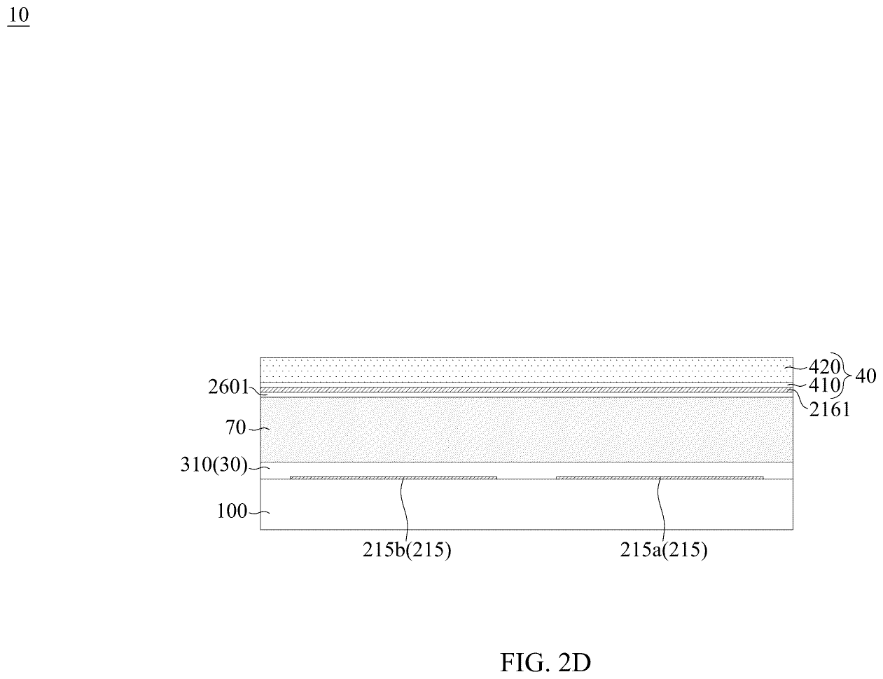

FIG. 2A shows a cross-sectional view of an organic light emitting device 10A. In some embodiments, FIG. 2A is a cross-sectional view along the line A-A′ in FIG. 1. In some embodiments, FIG. 2A is a cross-sectional view along the line A-A′ in FIG. 1 and only light emitting regions are illustrated. The spacer structure 30 includes several protrusions 310 to define a pattern of light emitting pixels. Each of the recesses is located between two adjacent protrusions 310 and provides a space for accommodating a light emitting pixel. Those skilled in the art should understand that the protrusions 310 are depicted in a disconnected manner, as shown in the cross-sectional view of FIG. 2A; however, the protrusions 310 are connected to one another by other portions of the spacer structure 30 as observed from the top view of FIG. 1.

As shown in FIG. 2A, in some embodiments, the organic light emitting device 10 is, for example, a light emitting device including an organic light emitting diode (OLED). In some embodiments, the organic light emitting device 10 includes a plurality of organic light emitting units (or referred to as light emitting pixels), for example, including at least an organic light emitting unit 101 (or referred to as a first organic light emitting unit) and an organic light emitting unit 102 (or referred to as a second organic light emitting unit). In some embodiments, the organic light emitting units 101 and 102 are disposed between the protrusions 310 and above the substrate 100. The organic light emitting units 101 and 102 may emit light having the same wavelength or light having different wavelengths.

In some embodiments, the organic light emitting device 10 includes a substrate 100, an electrode 215a (or referred to as a first bottom electrode), an electrode 216a (or referred to as a first top electrode), an electrode 216b (or referred to as a second top electrode), an electrode material layer 2161, an organic light emitting layer structure 20A, a spacer structure 30 (or referred to as a pixel defined layer), and a cover layer 40.

In some embodiments, the substrate 100 may include an array of transistors, which is configured to correspond to light emitting pixels in the light emitting layer 20. The substrate 100 may include several capacitors. In some embodiments, more than one transistor is configured to form a circuit with a capacitor and a light emitting pixel. In some embodiments, the substrate 100 is a glass substrate.

In some embodiments, the electrode 215a is disposed over the substrate 100. In some embodiments, the electrode 215a is an anode. In some embodiments, the electrode 215a includes a metal material, for example, Ag, Al, Mg, Au, AlCu alloy or AgMo alloy. In some embodiments, the electrode 215a includes indium tin oxide (ITO), indium zinc oxide (IZO) or other suitable materials. In some embodiments, the organic light emitting layer 260A and the organic light emitting layer 260B are disposed over the electrode 215a.

In some embodiments, the organic light emitting layer structure 20A is disposed over the electrode 215. In some embodiments, the organic light emitting layer structure 20A includes a light emitting layer 20 and an organic material layer 2601. In some embodiments, the light emitting layer 20 includes an organic light emitting layer 260A (or referred to as a first organic light emitting layer), and an organic light emitting layer 260B (or referred to as a second organic light emitting layer).

In some embodiments, the electrode 216a and the electrode 216b are disposed over the organic light emitting layer structure 20A. In some embodiments, the electrode 216a is disposed over the organic light emitting layer 260A, and the electrode 216b is disposed over the organic light emitting layer 260B. In some embodiments, the electrode 216a is in contact with the organic light emitting layer 260A, and the electrode 216b is in contact with the organic light emitting layer 260B. In some embodiments, the electrodes 216a and 216b may be further disposed over the spacer structure 30 (or the pixel defined layer). In some embodiments, the electrodes 216a and 216b include a metal material, for example, Ag, Al, Mg, Au, AlCu alloy or AgMo alloy. In some embodiments, the electrodes 216a and 216b include ITO, IZO, or another suitable material.

In some embodiments, the spacer structure 30 is disposed on the substrate 100 and partially covers the electrode 215a. In some embodiments, the spacer structure 30 is disposed between the organic light emitting layers 260A and 260B. In some embodiments, the spacer structure 30 is disposed between the electrodes 216a and the electrode 216b. In some embodiments, a pattern of the spacer structure 30 is designed according to a pixel layout. In some embodiments, the spacer structure 30 serves as a pixel defined layer (PDL). In some embodiments, the spacer structure 30 may include protrusions 310. In some embodiments, the protrusions 310 define pixel regions. In some embodiments, the electrode 215a is partially covered by the protrusions 310.

In some embodiments, the blocking strip 710 is disposed over the spacer structure 300 (serving as a pixel defined layer). In some embodiments, the electrode 216a and the electrode 216b are separated from each other by the blocking strip 710. In some embodiments, the electrodes 216a and 216b are electrically isolated or electrically insulated from each other by the blocking strip 710. In some embodiments, the thickness of the blocking strip 710 is greater than or equal to 1 μm, for example, 1 μm to 4 μm, or 2 μm to 3 μm. In some embodiments, the thickness of the blocking strip 710 is greater than the thickness of the electrode 216. In some embodiments, the thickness of the blocking strip 710 is more than 10 times the thickness of the electrode 216, for example, 20 to 30 times the thickness of the electrode 216. In some embodiments, the blocking strip 710 may include a photosensitive material. In some embodiments, the blocking strip 710 may include an inorganic oxide, for example, silicon oxide, silicon nitride or silicon oxynitride.

The blocking strip 710 may have a sloped or vertical sidewall 710s. In some embodiments, an included angle θ between an upper surface 710t and the sidewall 710s of the blocking strip 710 is between 70° and 110°. In some embodiments, an included angle θ between an upper surface 710t and the sidewall 710s of the blocking strip 710 is between 80° and 100°. As shown in FIG. 2A, in some embodiments, the blocking strip 710 has a sloped sidewall 710s, and the included angle θ between the upper surface 710t and the sidewall 710s of the blocking strip 710 is greater than 90°. In some embodiments, a cross-sectional width of the blocking strip 710 gradually increases in a direction toward the substrate 100 (that is, in a direction toward the spacer structure 30).

According to some embodiments, the material layers formed above the blocking strip 710 and the substrate 100, for example, an organic light emitting material layer and an electrode material layer, are disconnected by the blocking strip 710 to form parts separated from each other, as well as material parts remaining on the blocking strip 710. In some embodiments, the organic light emitting material layer is disconnected by the blocking strip 710 to form the organic light emitting layer 260A and the organic light emitting layer 260B separated from each other, as well as the organic material layer 2601 remaining on the blocking strip 710. In some embodiments, the electrode material layer is disconnected by the blocking strip 710 to form the electrodes 216a and 216b that are separated from each other, as well as the electrode material layer 2161 remaining on the blocking strip 710.

In some embodiments, the organic light emitting layer 260A is disposed between the electrode 215a and the electrode 216a, and the organic light emitting layer 260B is disposed between the electrode 215a and the electrode 216b. In some embodiments, the organic light emitting layer 260A and the organic light emitting layer 260B are separated by the blocking strip 710. In some embodiments, the thickness of the blocking strip 710 is greater than thicknesses of the organic light emitting layers 260A and 260B. In some embodiments, the thickness of the blocking strip 710 is more than 10 times the thicknesses of the organic light emitting layers 260A and 260B, for example, 10 to 20 times of the organic light emitting layers 260A and 260B. In some embodiments, the organic light emitting layers 260A and 260B emit light in the same color or different colors. In some embodiments, the wavelength of light emitted by the organic light emitting layer 260A is the same as the wavelength of light emitted by the organic light emitting layer 260B. In some embodiments, the wavelength of light emitted by the organic light emitting layer 260B is greater than the wavelength of light emitted by the organic light emitting layer 260A.

In some embodiments, the organic light emitting layers 260A and 260B and the organic material layer 2601 include one or more organic materials, which may be placed in any of the light emitting layers 260A and 260B and the organic material layer 2601. In some embodiments, the organic material has the absorptivity of greater than or equal to 50% for a specific wavelength. In some embodiments, the organic material has the absorptivity of greater than or equal to 60% for a specific wavelength. In some embodiments, the organic material has the absorptivity of greater than or equal to 70% for a specific wavelength. In some embodiments, the organic material has the absorptivity of greater than or equal to 80% for a specific wavelength. In some embodiments, the organic material has the absorptivity of greater than or equal to 90% for a specific wavelength. In some embodiments, the organic material has the absorptivity of greater than or equal to 95% for a specific wavelength. In some embodiments, the specific wavelength is not greater than 400 nm. In some embodiments, the specific wavelength is not greater than 350 nm. In some embodiments, the specific wavelength is not greater than 300 nm. In some embodiments, the specific wavelength is not greater than 250 nm. In some embodiments, the specific wavelength is not greater than 200 nm. In some embodiments, the specific wavelength is not greater than 150 nm. In some embodiments, the specific wavelength is not greater than 100 nm.

As shown in FIG. 2A, in some embodiments, each of the organic light emitting layers 260A and 260B and the organic material layer 2601 includes multiple material layers, for example, a hole injection layer (HIL) 261, a hole transport layer (HTL) 262, an electron barrier layer (EBL) 263, an organic emission layer (EML) 264, an electron transport layer (ETL) 265 and an electron injection layer (EIL) 266. In some embodiments, the organic light emitting unit 101 includes the electrode 215a (or referred to as the first bottom electrode), the organic light emitting layer 260A, and the electrode 216a (or referred to as the first top electrode). In some embodiments, the organic light emitting unit 102 includes the electrode 215a (or referred to as the first bottom electrode), the organic light emitting layer 260B, and the electrode 216b (or referred to as the second top electrode).

In some embodiments, the organic material layer 2601 is disposed over the blocking strip 710. In some embodiments, the organic material layer 2601 includes an organic material. In some embodiments, the electrode material layer 2161 is disposed over the blocking strip 710. In some embodiments, the organic material layer 2601 is separated from the organic light emitting layers 260A and 260B. In some embodiments, the material of the organic material layer 2601 is the same as that of the organic light emitting layers 260A and 260B.

In some embodiments, the organic material layer 2601 includes an extension portion formed on the sidewall of the blocking strip 710 and gradually decreases in a direction toward the substrate 100. In some embodiments, the extension portion of the organic material layer 2601 is formed on the sidewall 710s of the blocking strip 710 and gradually decreases in a direction toward the substrate 100. In some embodiments, the organic material layer 2601 includes two extension portions formed on two opposite sidewalls 710s of the blocking strip 710, and these two extension portions may have the same extension length or different extension length. For example, an extension length L1 of one extension portion of the organic material layer 2601 is greater than an extension length L2 of the other extension portion.

In some embodiments, the organic material layer 2601 includes the hole injection layer (HIL) 261, the hole transport layer (HTL) 262, the electron barrier layer (EBL) 263, the organic emission layer (EML) 264, the electron transport layer (ETL) 265 and the electron injection layer (EIL) 266. In some embodiments, each of the hole injection layer (HIL) 261, the hole transport layer (HTL) 262, the electron barrier layer (EBL) 263, the organic emission layer (EML) 264, the electron transport layer (ETL) 265 and the electron injection layer (EIL) 266 of the organic material layer 2601 includes two extension portions formed on two opposite sidewalls 710s of the blocking strip 710. In some embodiments, the extension portions of the hole injection layer (HIL) 261, the hole transport layer (HTL) 262, the electron barrier layer (EBL) 263, the organic emission layer (EML) 264, the electron transport layer (ETL) 265 and the electron injection layer (EIL) 266 of the organic material layer 2601 may have the same or different extension lengths.

In some embodiments, the electrode material layer 2161 is disposed on the upper surface 710t of the blocking strip 710 and extends onto the sidewall 710s, and the electrode material layer 2161 is separated from the electrode 216a and the electrode 216b. In some embodiments, the electrode material layer 2161 includes an extension portion formed on the sidewall 710s of the blocking strip 710 and narrows gradually in a direction toward the substrate 100. In some embodiments, the electrode material layer 2161 includes two extension portions formed on two opposite sidewalls 710s of the blocking strip 710, and these two extension portions may have the same or different extension lengths. For example, an extension length L3 of one extension portion of the electrode material layer 2161 is greater than an extension length L4 of the other extension portion.

Moreover, in some embodiments, after the material layer formed above the blocking strip 710 and the substrate 100 is disconnected by the blocking strip 710, it is possible that a residue structure 260Rs is left on the sidewall 710s of the blocking strip 710. The residue structure 260Rs is separated from the electrode 216a and the electrode 216b. In some embodiments, the residue structure 260Rs includes multiple residues (for example, residues 260R1 and 260R2 shown in the drawing), and at least some residues are connected to one another. In some embodiments, these residues have irregular forms and different sizes. Moreover, different residues may include the same number of layers or a combination of different numbers of material layers. In some embodiments, each residue may include an organic material, an electrode material, or a combination thereof.

In some embodiments, some irregularly shaped organic material fragments 2062 connected to or separated from one another remain on the sidewall 710s of the blocking strip 710. These organic material fragments 2602 are formed together with the organic material layer 2601. Moreover, it should be noted that FIG. 2A shows only a cross section of the blocking strip 710 with non-connected organic material fragments 2602; however, in other cross sections of the blocking strip 710 that are not shown, some connected organic material fragments 2602 may remain on the sidewall 710s.

In some embodiments, the organic material fragments 2602 of each residue may include the same number of material layers as the organic material layer 2601. For example, the organic material fragments 2602 of the residue 260R1 in FIG. 2A have substantially the same number of material layers as the organic material layer 2601. In some embodiments, each of the organic material fragments 2602 may include different numbers of material layers from the organic material layer 2601. For example, the organic material fragments 2602 of the residue 260R2 in FIG. 2A may have substantially less material layers than the organic material layer 2601.

In some embodiments, some irregularly shaped electrode material fragments 2162 connected to or separated from one another remain on the sidewall 710s of the blocking strip 710. These electrode material fragments 2162 are formed together with the electrode material layer 2161. In some embodiments, the electrode material fragments 2162 of the residue are formed on the sidewall 710s of the blocking strip 710, and are separated from the electrode 216a and the electrode 216b. In some embodiments, the electrode material fragments 2162 partially cover the organic material fragments 2602. Moreover, in some embodiments, at least some electrode material fragments 2162 are connected. Joints of the electrode material fragments 2162 may exhibit a form of elongated filaments. It should be noted that FIG. 2A shows only a cross section of the blocking strip 710 with connected electrode material fragments 2162; however, in other cross sections of the blocking strip 710 that are not shown, some non-connected electrode material fragments 2162 may remain on the sidewall 710s.

In some embodiments, the spacer structure 30 (or the pixel defined layer) includes an organic insulating material. In some embodiments, the spacer structure 30 includes a photosensitive material. In some embodiments, the spacer structure 30 may further include quantum dots, which have excellent light absorption performance. In some embodiments, the spacer structure 30 may further include a carbon black material, for example, carbon black nanoparticles, conductive fibers containing carbon black, or the like. In some embodiments, the spacer structure 30 may further include a black material, which has the absorptivity of more than 90%, 95%, 99%, 99.5%, or 99.9% for visible light.

In some embodiments, the spacer structure 30 has the absorptivity of greater than or equal to 50% for a specific wavelength. In some embodiments, the spacer structure 30 has the absorptivity of greater than or equal to 60% for a specific wavelength. In some embodiments, the spacer structure 30 has the absorptivity of greater than or equal to 70% for a specific wavelength. In some embodiments, the spacer structure 30 has the absorptivity of greater than or equal to 80% for a specific wavelength. In some embodiments, the spacer structure 30 has the absorptivity of greater than or equal to 90% for a specific wavelength. In some embodiments, the spacer structure 30 has the absorptivity of greater than equal to 95% for a specific wavelength. In some embodiments, the specific wavelength is not greater than 400 nm. In some embodiments, the specific wavelength is not greater than 350 nm. In some embodiments, the specific wavelength is not greater than 300 nm. In some embodiments, the specific wavelength is not greater than 250 nm. In some embodiments, the specific wavelength is not greater than 200 nm. In some embodiments, the specific wavelength is not greater than 150 nm. In some embodiments, the specific wavelength is not greater than 100 nm.

In some embodiments, the cover layer 40 includes a capping layer 410 and an encapsulation layer 420. In some embodiments, the capping layer 410 is arranged over the electrode 216a, the electrode 216b, the blocking strip 710 and the residue structure 260Rs (if present), and is substantially conformal with the electrode 216a, the electrode 216b, the blocking strip 710 and a non-flat upper surface of the residue structure 260Rs (if present). In some embodiments, the capping layer 410 may include a dielectric material or an inorganic insulating material, for example, SiO₂. In some embodiments, the capping layer 410 may include a hole transport layer material to extract light lost inside the organic light emitting device so as to improve light emitting efficiency. The capping layer 410 may also be referred to as a light extraction layer.

In some embodiments, the encapsulation layer 420 is disposed over the capping layer 410, and is substantially conformal with a non-flat upper surface of the capping layer 410. The encapsulation layer 420 may include an oxide, for example, SiO₂. In some embodiments, the encapsulation layer 420 is substantially conformal with a non-flat upper surface of the capping layer 410, and includes a plurality of recesses corresponding to the organic light emitting layers 260A and 260B. In some embodiments, the electrode 216a and the electrode 216b are separated from each other by the blocking strip 710, the capping layer 410 and the encapsulation layer 420. The encapsulation layer 420 may include a polymer organic material, for example, an epoxy-based material.

According to some embodiments of the present disclosure, the multiple electrodes 216 are separated from one another by the blocking strip 710, and are orthogonal to the multiple electrodes 215 of multiple light emitting units (or light emitting pixels). With the height provided by the blocking strip 710, the multiple electrodes 216 may be physically separated. Moreover, the spacer structure 30 (serving as the pixel defined layer) below the blocking strip 710 may include protrusions 310 for defining pixel regions, and a height difference between the blocking strip 710 and the substrate 100 may be further increased. Thus, according to some embodiments of the present disclosure, it is not necessary to pattern an electrode material using photolithography and etching processes to form multiple, separated electrodes 216. This simplifies the process for manufacturing the electrodes 216, enabling the individual control of the lighting of multiple light emitting units (or light emitting pixels), allowing the organic light emitting device 10 to display a variety of predetermined light emitting patterns. For example, when the organic light emitting device 10 is applied to a sighting device, it can be designed based on ballistics to present multi-point display images.

Moreover, according to some embodiments of the present disclosure, with the height difference provided by the blocking strip 710 (or a height difference provided by both the blocking strip 710 and the spacer structure 30 below), the multiple electrodes 216 may be physically separated, hence alleviating or preventing etching damage of the organic light emitting layers 260A and 260B below the electrodes 216, further improving reliability and yield rate of the organic light emitting device 10.

FIG. 2B shows a cross-sectional view of an organic light emitting device 10B. In some embodiments, FIG. 2B shows a cross-sectional view of the organic light emitting unit 10 in FIG. 1. In some embodiments, FIG. 2B shows a cross-sectional view along the line A-A′ in FIG. 1. In some embodiments, FIG. 2B shows a cross-sectional view along the line A-A′ in FIG. 1 and only light emitting regions are illustrated. The structure of FIG. 2B is similar to the structure of FIG. 2A, and the differences between the two structures are described below.

In some embodiments, the blocking strip 710 has substantially vertical sidewalls 710s. In some embodiments, an included angle θ between the upper surface 710t and the sidewall 710s of the blocking strip 710 is substantially 90°. The vertical sidewall 710s of the blocking strip 710 allows material layers (for example, an organic light emitting material layer and an electrode material layer) formed above the substrate 100, once disconnected by the blocking strip 710, to more easily form material parts disconnected from one another. For example, multiple organic light emitting layers (such as the organic light emitting layers 260A and 260B) disconnect from each other, and multiple electrodes 216 (for example, the electrodes 216a and 216b) disconnect from each other.

Moreover, the vertical sidewall 710s of the blocking strip 710 reduces the amount and probability of residues formed on the sidewall 710s. In some embodiments, for the multiple residues on the sidewall 710s, the volume of the residue gets larger as getting closer to the upper surface 710t, and the volume of the residue gets smaller as getting farther away from the upper surface 710t (closer to the spacer structure 30). As the embodiment shown in FIG. 2B, the volume of the residue 260R1 at an upper part of the sidewall 710s (closer to the upper surface 710t) is larger, and the volume of the residue 260R2 at a lower part of the sidewall 710s (closer to the spacer structure 30) is smaller. In some embodiments, on the sidewall 710s of the blocking strip 710, the thickness of the residue is thinner as it is located further down the sidewall 710s.

In some embodiments, each residue may include an organic material, an electrode material, or a combination thereof. In some embodiments, the organic material fragment 2602 of the residue at the upper part of the sidewall 710s has a greater thickness, and the organic material fragment 2602 of the residue at the lower part of the sidewall 710s has a smaller thickness. In some embodiments, the electrode material fragment 2162 of the residue closer to an upper part of the sidewall 710s has a greater thickness than that of the electrode material fragment 2162 of the residue closer to a lower part of the sidewall 710s. Moreover, in some embodiments, the thickness of each material layer of each residue, such as the organic material fragments 2602 and the electrode material fragments 2162, on the sidewall 710s gradually decreases in a direction away from the upper surface 710t.

FIG. 2C shows a cross-sectional view of an organic light emitting device 10C. In some embodiments, FIG. 2C shows a cross-sectional view of the organic light emitting unit 10 in FIG. 1. In some embodiments, FIG. 2C shows a cross-sectional view along the line A-A′ in FIG. 1. In some embodiments, FIG. 2C shows a cross-sectional view along the line A-A′ in FIG. 1 and only light emitting regions are illustrated. The structure of FIG. 2C is similar to the structure of FIG. 2A, and the differences between the two structures are described below.

In some embodiments, the blocking strip 710 has a sloped sidewall 710s. In some embodiments, an included angle θ between the upper surface 710t and the sidewall 710s of the blocking strip 710 is less than 90°. In some embodiments, the included angle θ is between 80° and 90°. In some embodiments, a cross-sectional width of the blocking strip 710 gradually decreases in a direction toward the substrate 100 (that is, in a direction toward the spacer structure 30). Thus, the blocking strip 710 is able to more effectively disconnect the material layers (including an organic light emitting layer and an electrode material layer) to form multiple organic light emitting layers (for example, the organic light emitting layers 260A and 260B) and multiple electrodes 216 (for example, the electrodes 216a and 216b) disconnected from each other. Thus, the problem of single point lighting failure caused by short circuit between adjacent light emitting units (or light emitting pixels) can be effectively prevented. Moreover, according to some embodiments of the present disclosure, it is not necessary to pattern an organic light emitting material and an electrode material using photolithography and etching processes to form multiple separated organic light emitting layers and multiple separated electrodes. This simplifies the process for manufacturing the organic light emitting layers and the electrodes. Moreover, after the material layer formed above the substrate 100 is disconnected by the blocking strip 710, the blocking strip 710, which has an inverted trapezoidal cross section, can make it more difficult for residues to form on its sidewall 710s.

FIG. 2D shows a cross-sectional view of the organic light emitting device 10. In some embodiments, FIG. 2D shows a cross-sectional view along the line D-D′ in FIG. 1. In some embodiments, FIG. 2D shows a cross-sectional view along the line D-D′ in FIG. 1 and only light emitting regions are illustrated.

In some embodiments, the electrodes 215a and 215b are separated from each other by the spacer structure 30 (or the pixel defined layer). In some embodiments, the electrodes 215a and 215b are separated from the blocking strip 710 by the spacer structure 30 (or the pixel defined layer).

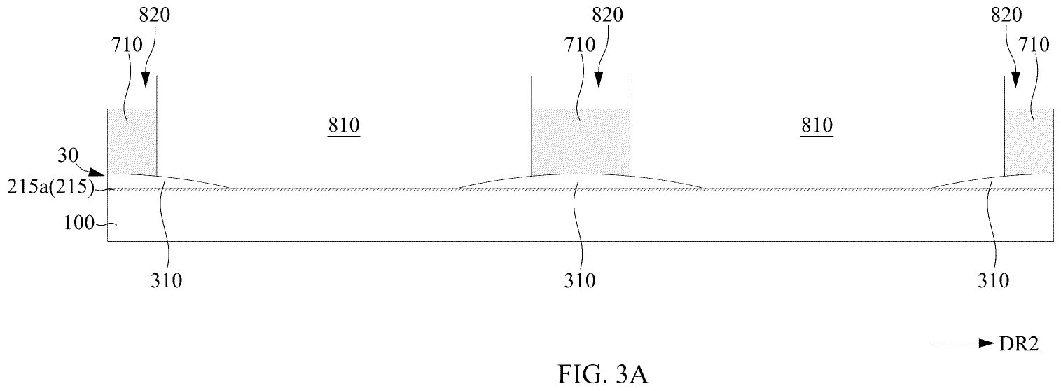

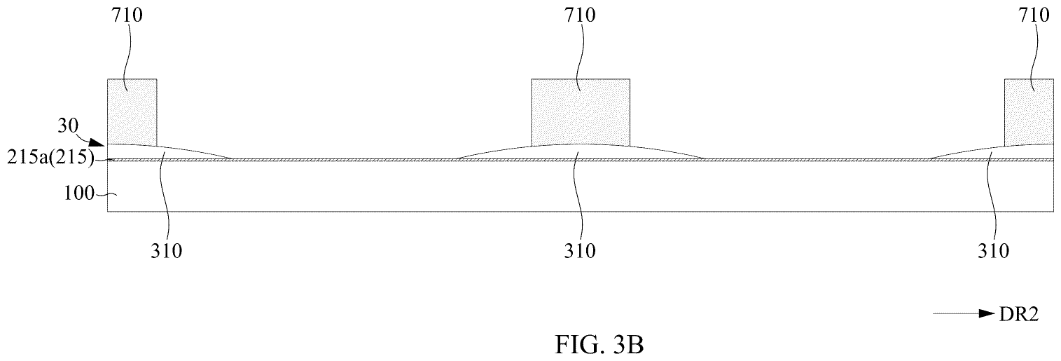

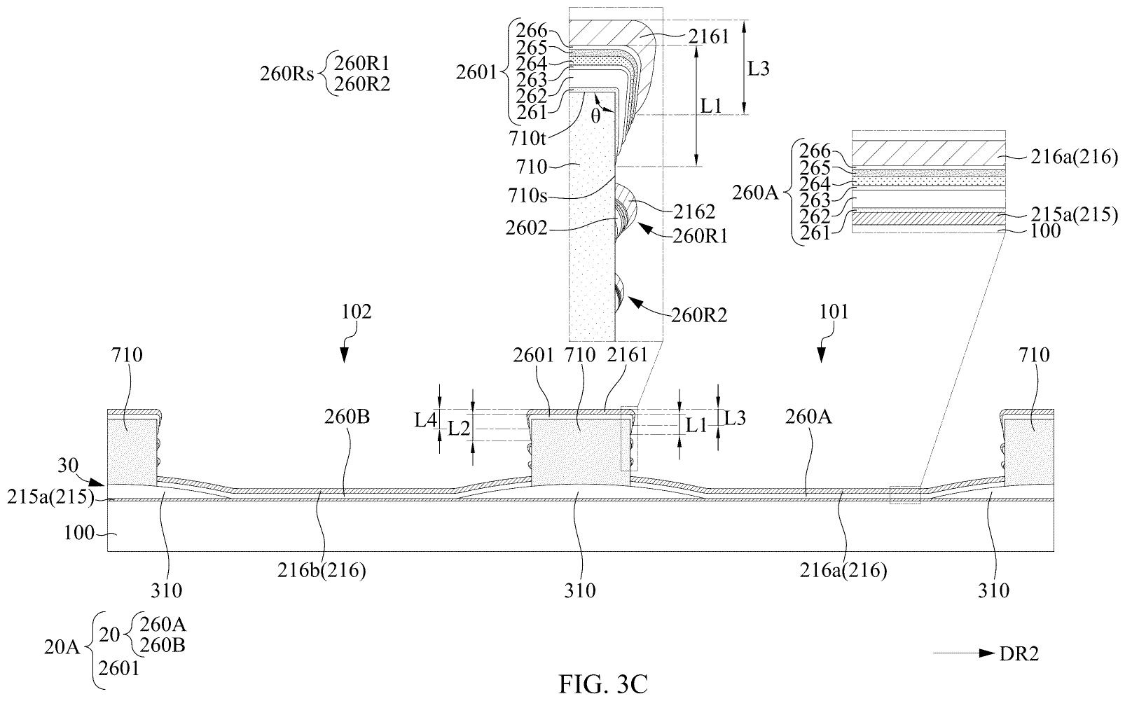

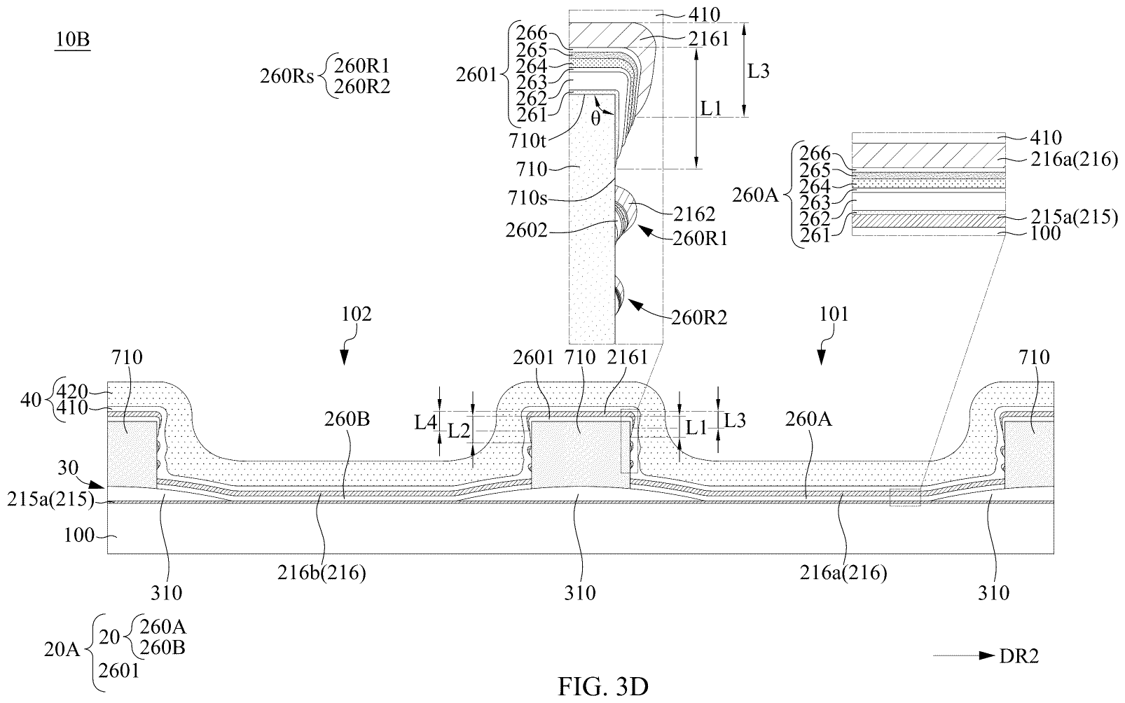

FIG. 3A to FIG. 3D depict a manufacturing method of an organic light emitting device 10B according to some embodiments.

As shown in FIG. 3A, in some embodiments, a substrate 100 is provided, an electrode 215a is arranged over the substrate 100, and several protrusions 310 (or a spacer structure 30) are formed over the electrode 215a. In some embodiments, multiple electrodes 215 (referring to FIG. 1) are formed over the substrate 100, and the spacer structure 30 is formed over the multiple electrodes 215. The multiple electrodes 215 may be manufactured by photolithography and etching processes. Next, in some embodiments, a photosensitive layer 810 is formed over the spacer structure 30 and the electrode 215a. In some embodiments, a photosensitive material is formed by coating. Moreover, in some embodiments, the photosensitive material is patterned by a lithography process to form a photosensitive layer 810, such that a portion of the protrusion 310 is exposed through a groove 820. Next, in some embodiments, a blocking material layer 700 is formed in the groove 820. In some embodiments, the blocking material layer 700 is formed by coating.

As shown in FIG. 3B, in some embodiments, the photosensitive layer 810 is removed. In some embodiments, the photosensitive layer 810 is removed by a wet etching process.

Next, as shown in FIG. 3C, in some embodiments, an organic light emitting layer structure 20A and an electrode material layer are formed over the spacer structure 30, the electrode 215a and the blocking strip 710 (of the blocking structure 70; FIG. 1).

In some embodiments, an organic light emitting material layer is formed above the blocking strip 710 (of the blocking structure 70; FIG. 1) and the substrate 100, such that the organic light emitting material layer is disconnected by the blocking strip 710 to form the organic light emitting layer 260A and the organic light emitting layer 260B separated from each other. In some embodiments, an organic light emitting material layer is blanketly formed over the spacer structure 30, the electrode 215a and the blocking strip 710 by evaporation, such that the organic light emitting material layer at an entire surface is disconnected by the blocking strip 710 to form the organic light emitting layer 260A and the organic light emitting layer 260B that are separated from each other, the organic material layer 2601 remaining on the blocking strip 710, and the organic material layer 2602 remaining on the sidewall 710s of the blocking strip 710.

In some embodiments, a hole injection layer (HIL) 261 is formed over the surfaces of the spacer structure 30, the electrode 215a and the blocking strip 70 by evaporation, a hole transport layer (HTL) 262 is formed over the hole injection layer (HIL) 261, an electron barrier layer (EBL) 263 is formed over the hole transport layer (HTL) 262, an organic emission layer (EML) 264 is formed over the electron barrier layer (EBL) 263, an electron transport layer (ETL) 265 is formed over the organic emission layer (EML) 264, and an electron injection layer (EIL) 266 is formed over the electron transport layer (ETL) 265.

In some embodiments, an electrode material layer is formed above the blocking structure 70 and the substrate 100, such that the electrode material layer is disconnected by the blocking structure 70 to form the electrode 216a and the electrode 216b separated from each other. In some embodiments, an electrode material layer is blanketly formed over the spacer structure 30, the electrode 215a and the blocking strip 710 (of the blocking structure 70) by evaporation, such that the electrode material layer at an entire surface is disconnected by the blocking strip 710 to form the electrode 216a and the electrode 216b that are separated from each other, the electrode material layer 2161 remaining on the blocking strip 710, and the residues 260R1 and 260R2 remaining on the sidewall 710s of the blocking strip 710.

As shown in FIG. 3D, in some embodiments, a capping layer 410 is disposed over the electrodes 216a and 216b. In some embodiments, the capping layer 410 is formed by evaporation. Next, in some embodiments, an encapsulation layer 420 is disposed over the capping layer 410. In some embodiments, the capping layer 410 is formed by evaporation. Up to this point, the organic light emitting device 10B shown in FIG. 2B is formed.

The features of some embodiments are given in brief in the description above for a person skilled in the art to better understand various aspects of the present disclosure. A person skilled in the art would able to understand that the present disclosure can be used as the basis for designing or modifying other manufacturing processes and structures so as to achieve the same objects and/or the same advantages of the embodiments described in the present application. A person skilled in the art would also be able to understand that such structures do not depart from the spirit and scope of the disclosure of the present application, and various changes, substitutions and replacements may be made by a person skilled in the art without departing from the spirit and scope of the present disclosure.

What is claimed is:

1. An organic light emitting device, comprising:
a substrate;
a first bottom electrode, disposed over the substrate;
an organic light emitting layer structure, disposed over the first bottom electrode;
a first top electrode and a second top electrode, disposed over the organic light emitting layer structure;
a pixel defined layer, disposed over the substrate; and
a blocking strip, disposed over the pixel defined layer, wherein the first top electrode and the second top electrode are separated by the blocking strip.

2. The organic light emitting device of claim 1, further comprising:
an electrode material layer, disposed on an upper surface and a sidewall of the blocking strip, and separated from the first top electrode and the second top electrode.

3. The organic light emitting device of claim 1, further comprising:
a residue structure, disposed on a sidewall of the blocking strip, the residue structure separated from the first top electrode and the second top electrode.

4. The organic light emitting device of claim 3, wherein the residue structure comprises a plurality of residues, the residues comprise electrode material fragments, and the electrode material fragments of at least two different residues are connected.

5. The organic light emitting device of claim 3, wherein at least one of the residues comprises:
an organic material fragment, disposed on the sidewall of the blocking strip; and
an electrode material fragment, disposed on the sidewall of the blocking strip and partially covering the organic material fragment.

6. The organic light emitting device of claim 1, further comprising:
a first residue, disposed on a sidewall of the blocking strip; and
a second residue, disposed on the sidewall of the blocking strip, and disposed between the first residue and the substrate;
wherein, the second residue is separated from the first top electrode and the second top electrode.

7. The organic light emitting device of claim 6, wherein the second residue is separated from the first residue.

8. The organic light emitting device of claim 6, wherein the first residue and the second residue include different numbers of material layers.

9. The organic light emitting device of claim 6, wherein the first residue and the second residue have different sizes.

10. The organic light emitting device of claim 1, wherein an included angle between an upper surface and a sidewall of the blocking strip is between 80° and 100°.

11. The organic light emitting device of claim 1, wherein the blocking strip comprises a sloped sidewall.

12. The organic light emitting device of claim 1, wherein a cross-sectional width of the blocking strip gradually increases or gradually decreases in a direction toward the substrate.

13. The organic light emitting device of claim 1, wherein thickness of the blocking strip is at least 20 times thickness of the first top electrode or the second top electrode.

14. The organic light emitting device of claim 1, wherein the organic light emitting layer structure comprises:
a first organic light emitting layer, disposed between the first bottom electrode and the first top electrode; and
a second organic light emitting layer, disposed between the first bottom electrode and the second top electrode, wherein the first organic light emitting layer is separated from the second organic light emitting layer by the blocking strip.

15. The organic light emitting device of claim 1, wherein the organic light emitting layer structure further comprises:
a plurality of organic material layers, disposed at an upper surface of the blocking strip and extending to a top of a sidewall of the blocking strip.

16. The organic light emitting device of claim 1, wherein extension directions of the first top electrode and the second top electrode are substantially parallel to an extension direction of the blocking strip.

17. A manufacturing method of an organic light emitting device, comprising:
providing a substrate;
forming a first bottom electrode over the substrate;
forming a pixel defined layer over the substrate, wherein the pixel defined layer partially covers the first bottom electrode;
forming a blocking strip over the pixel defined layer;
forming an organic light emitting layer structure over the first bottom electrode and the blocking strip; and
forming a top electrode material layer above the blocking strip and the substrate, such that the top electrode material layer is disconnected by the blocking strip to form a first top electrode and a second top electrode that are separated from each other.

18. The manufacturing method of claim 17, wherein the forming of the blocking strip comprises:
forming a blocking material layer over the pixel defined layer; and
patterning the blocking material layer to form the blocking strip, wherein an included angle between an upper surface and a sidewall of the blocking strip is between 80° and 100°.

19. The manufacturing method of claim 17, wherein when the blocking strip disconnects the top electrode material layer, a residue structure is further formed on the sidewall of the blocking strip, wherein the residue structure is separated from the first top electrode and the second top electrode.

20. The manufacturing method of claim 19, further comprising:
forming a cover layer above the first top electrode and the second top electrode, wherein the cover layer covers the blocking strip and the residue structure.
